(19) United States
(12) Patent Application Publication
(10) Pub. No.: US 2007/0023864 A1
(43) Pub. Date: Feb. 1, 2007

(54) METHODS OF FABRICATING BIPOLAR TRANSISTOR FOR IMPROVED ISOLATION, PASSIVATION AND CRITICAL DIMENSION CONTROL

(75) Inventor: Marwan H. Khater, Long Island City, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/161,286

(22) Filed: Jul. 28, 2005

(51) Int. Cl. H01L 29/73; H01L 21/331

(52) U.S. Cl. 257/565; 257/592; 438/309; 438/350; 438/345

(57) ABSTRACT

A first (e.g. replaceable or disposable) dielectric spacer formed on a sidewall of a dummy emitter mandrel is removed after a raised extrinsic base layer and covering dielectric layer are formed. Thereafter, a second dielectric spacer is formed within the opening that results. As a result, the second dielectric spacer, which is not subjected to RIE processing, provides a desired level of isolation and tighter emitter final critical dimension than that which could be achieved through the technique described in the prior art. In a particular embodiment, an additional layer of silicon nitride is disposed over a passivation oxide layer as a sacrificial layer which protects the passivation oxide layer from being reduced in thickness and/or being undercut during the RIE process and one or more cleaning processes conducted after the RIE process.

### BACKGROUND OF THE INVENTION

The present invention relates to semiconductor devices and processing.

FIG. 1 illustrates a known method of forming a bipolar transistor having a raised extrinsic base self-aligned to an emitter of the transistor. As shown in FIG. 1, a mandrel 10 is formed in a location to be occupied by the emitter, the mandrel thus being a “dummy emitter” mandrel. The mandrel includes an etch stop layer, which is typically a sacrificial oxide layer 11, over which a lower layer of polysilicon 12 and an upper layer of silicon nitride 14 are disposed. The oxide etch stop layer can either be thermally grown as a silicon dioxide layer from the semiconductor material present at the interface to the intrinsic base layer 16, or be deposited such as by a chemical vapor deposition (“CVD”) process, such as a rapid thermal CVD (“RTCVD”) process, for example.

A dielectric spacer 18 is provided on a sidewall of the mandrel 10, after which doped polysilicon or other conductive material is deposited and recessed to provide a raised extrinsic base layer 20 in the region surrounding the dielectric spacer 18. As shown in FIG. 2, a layer 22 of silicon oxide is formed to cover the raised extrinsic base to a height generally level with the top surface 24 of the mandrel. Referring to FIG. 3A, subsequently, the nitride layer and the polysilicon layer of the mandrel are removed, such as by a reactive ion etch (RIE) process to form an emitter opening 28. This process may or may not be conducted in a manner which is selective to the material from which the dielectric spacer 18 is made. As a result, the spacer may become eroded during the RIE process. As shown in FIG. 3A, both the height of the spacer 26 above the intrinsic base layer and the width of the spacer decrease from their initial values from erosion due to the RIE process and one or more cleaning processes performed after the RIE process. The oxide etch stop layer 11 can also become eroded during the RIE process or post-RIE clean process, and it can also become undercut in areas 31 where the oxide layer underlies the spacer 26.

These undesirable after-effects of the RIE process are generally more pronounced when the oxide layer is a deposited oxide layer than when it is a thermally grown layer. A thermally grown oxide layer tends to be denser and less easily etched than a deposited oxide layer. FIG. 3B illustrates an extreme case of damage resulting from the RIE process and post clean processes when the RIE process fails to stop or end point when it reaches the oxide etch stop layer 11. As shown in FIG. 3B, the oxide etch stop layer is completely removed from the opening 28, allowing the RIE process to seriously damage the intrinsic base layer 16 that lies immediately below the oxide etch stop layer. After experiencing the level of damage shown in FIG. 3B, the transistor which eventually results from the fabrication process becomes unusable. The quality of its intrinsic base layer and the degree of control exercised over its dimensions are critical factors determining the ultimate performance of the transistor.

As also shown in FIG. 3B, the oxide layer becomes undercut underneath the dielectric spacer 26 to a point that exposes the polysilicon of the raised extrinsic base 20. Such undercutting can make the final transistor inoperative. With the polysilicon material of the raised extrinsic base 20 exposed, the semiconductor material of the emitter which is later deposited within the opening 28 might not be in contact with or otherwise be not properly isolated from the raised extrinsic base. Summarizing, the spacer and oxide etch stop layer according to the prior art can be eroded and damaged to a point where they no longer serve their intended functions of isolating the emitter from the raised extrinsic base and protecting the intrinsic base layer from damage. More effective ways of accomplishing these functions are needed.

### SUMMARY OF THE INVENTION

According to one aspect of the invention, a first dielectric spacer formed on a sidewall of a dummy emitter mandrel is removed after a raised extrinsic base layer and covering dielectric layer are formed. Thereafter, the dummy emitter mandrel as well as the first dielectric spacer are removed, after which a second dielectric spacer is formed within the opening that results. As a result, the second dielectric spacer, which is not subjected to RIE processing, provides a desired level of isolation and passivation to the bipolar transistor at tighter dimensions than that which could be achieved through the technique described above as background. In a particular embodiment, an additional layer of silicon nitride is disposed over the oxide etch stop layer as a sacrificial layer which protects the oxide etch stop layer from being reduced in thickness and/or being undercut during the RIE process and one or more cleaning processes conducted after the RIE process.

According to one aspect of the invention, a method is provided for making a bipolar transistor. Such method includes forming a portion of the bipolar transistor including a collector region, and an intrinsic base layer overlying the collector region. A mandrel has an upwardly rising wall overlying a first portion of the intrinsic base layer, a replaceable dielectric spacer is disposed on the wall of the mandrel, and a raised extrinsic base layer overlies a second portion of the intrinsic base layer. The mandrel is then removed by etching to form an emitter opening having an upwardly rising wall. A replacement dielectric spacer is then formed on the wall of the emitter opening and an emitter layer is formed which is separated from the raised extrinsic base layer by at least the replacement dielectric spacer.

According to a particular aspect of the invention, a method is provided for making a bipolar transistor. Such method includes forming a collector region in a semiconductor substrate, an intrinsic base layer overlying the collector region and a first dielectric layer over the intrinsic base layer. A mandrel is then formed over the first dielectric layer, the mandrel including a first dielectric sidewall spacer. A portion of the first dielectric layer overlying the intrinsic base layer which is not covered by the mandrel or the first dielectric spacer is then removed. A raised extrinsic base layer is formed in conductive communication with the intrinsic base layer and a mandrel opening is formed in the raised extrinsic base layer by etching the mandrel including the first dielectric spacer. A second dielectric spacer is formed on a sidewall of the opening and an emitter layer is formed within the opening, the emitter layer being separated from the raised extrinsic base layer by the second dielectric spacer.

According to yet another aspect of the invention, a bipolar transistor is provided which includes a collector region and an intrinsic base layer overlying the collector region. The bipolar transistor further includes a raised extrinsic base layer in conductive communication with the intrinsic base layer and an emitter layer in conductive communication with the intrinsic base layer. A spacer separates the raised extrinsic base layer from the emitter layer, the spacer having a lower layer consisting essentially of a first dielectric material, and an upper layer disposed above the lower layer consisting essentially of a second dielectric material, the spacer having a uniform, controllable thickness.

### BRIEF DESCRIPTION OF THE DRAWINGS

FIGS. 1, 2, 3A and 3B illustrate steps in a process of fabricating a bipolar transistor in accordance with a prior art fabrication method.

FIGS. 4 through 12 illustrate steps in a process of fabricating a bipolar transistor in accordance with a first preferred embodiment of the invention.

FIGS. 13 through 19 illustrate steps in a process of fabricating a bipolar transistor in accordance with a second preferred embodiment of the invention.

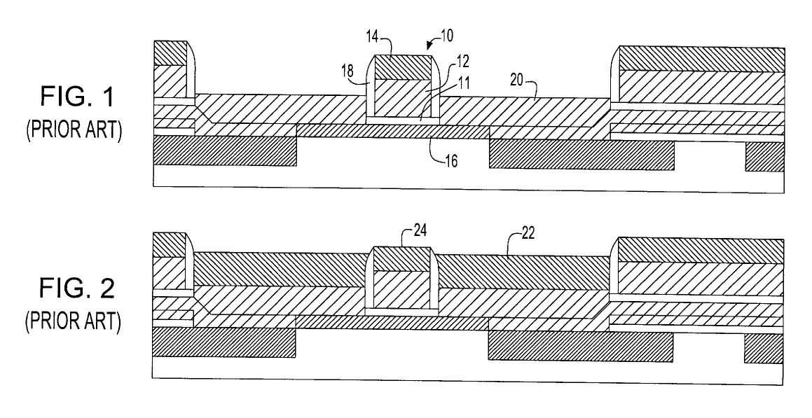

### DETAILED DESCRIPTION

Accordingly, methods are provided herein which address the above-described difficulties faced by the processing described above in the background. In the embodiments of the invention described herein, a first dielectric spacer which is formed on a sidewall of a dummy emitter mandrel is removed after the raised extrinsic base layer and covering dielectric layer are formed. Thereafter, a second dielectric spacer is formed within the opening that results. In other words, the first spacer is used as a replaceable or disposable spacer to protect the sidewalls of the raised extrinsic base layer and covering dielectric layer during the removal of the dummy emitter mandrel. The second dielectric spacer, not being subjected to damage from RIE processing, therefore, provides a desired level of isolation between the raised extrinsic base and the emitter and tighter emitter final critical dimension control than that which could be achieved through the technique described above as background. In a particular embodiment, a layer of silicon nitride is disposed over a passivation oxide layer as a sacrificial layer which protects the passivation oxide layer from being reduced in thickness and/or being undercut during the RIE process and one or more cleaning processes conducted after the RIE process. In such embodiment, the passivation oxide layer is covered by the silicon nitride layer in order to preserve its integrity to provide better passivation between the base and the emitter after the second spacer is formed.

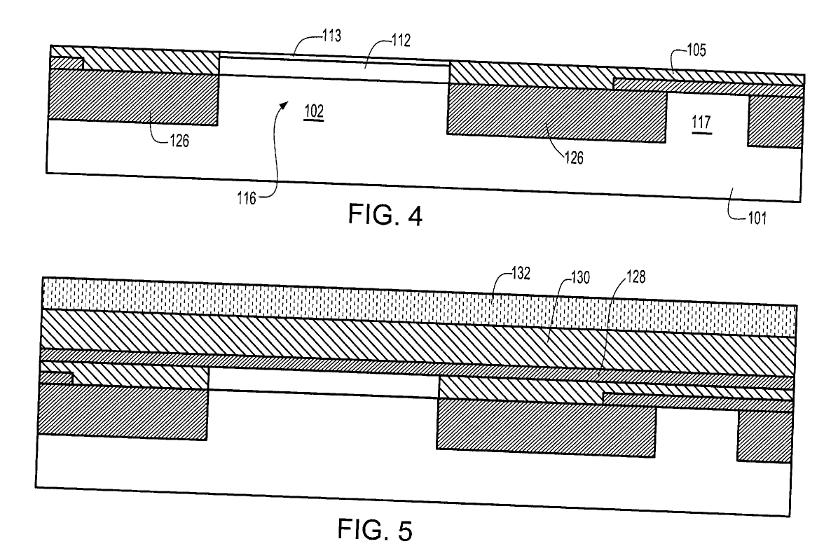

A method of fabricating a bipolar transistor according to an embodiment of the invention is illustrated in FIGS. 4 through 12. As depicted in FIG. 4, a single-crystal silicon substrate 101 is patterned to form a first active area 102, a second active area 117, and shallow trench isolations 126 between the active areas 102 and 117. The shallow trench isolations 126 are formed by directionally etching trenches in the substrate 101, and then filling the trenches with a dense oxide, such as may be provided by high electron density plasma (HDP) deposition.

A layer 105 of dielectric material, preferably consisting of silicon dioxide, e.g., a TEOS deposited oxide, is deposited over the substrate and photolithographically patterned to expose the first active area 102 but not the second active area 117. Active area 102 is ion implanted, or otherwise doped to form a collector region 116. When an npn type bipolar transistor is to be made, the dopant source for this step is an n-type dopant such as arsenic and/or phosphorous.

As also depicted in FIG. 4, a layer 112 of semiconductor material including a dopant of the opposite type as the collector region 116 is epitaxially grown onto the surface of the substrate in active area 102. This layer 112 becomes an intrinsic base layer of the transistor when completed. When an npn bipolar transistor is to be made, the dopant source during this step is a p-type dopant such as boron. Preferably, the intrinsic base layer 112 includes a semiconductor alloy such as silicon germanium (SiGe) having a substantial percentage content of germanium. Such layer 112 desirably has a germanium content which is greater than 20%, while the silicon content makes up a complementary percentage. A small amount of carbon may also be incorporated, i.e., less than one percent, to reduce diffusion of dopants in subsequent processing. Preferably, a second layer 113 of semiconductor material is epitaxially grown over the intrinsic base layer 112, the second layer 113 being thinner than layer 112 and having a lowered dopant concentration compared to the intrinsic base layer 112. This layer 113 is subject to being doped by overlying layers which are subsequently formed in contact therewith, such as due to dopant outdiffusion from the overlying layers. In one embodiment of the invention, the SiGe layer 112 is grown using non-selective, i.e., blanket epitaxy. For that reason, while the layers 112 and 113 are grown as single-crystal semiconductor layers on the active area region 102 of the substrate, layers of polycrystalline semiconductor material are deposited onto other areas in which the STI regions 126 and oxide layer 105 are disposed.

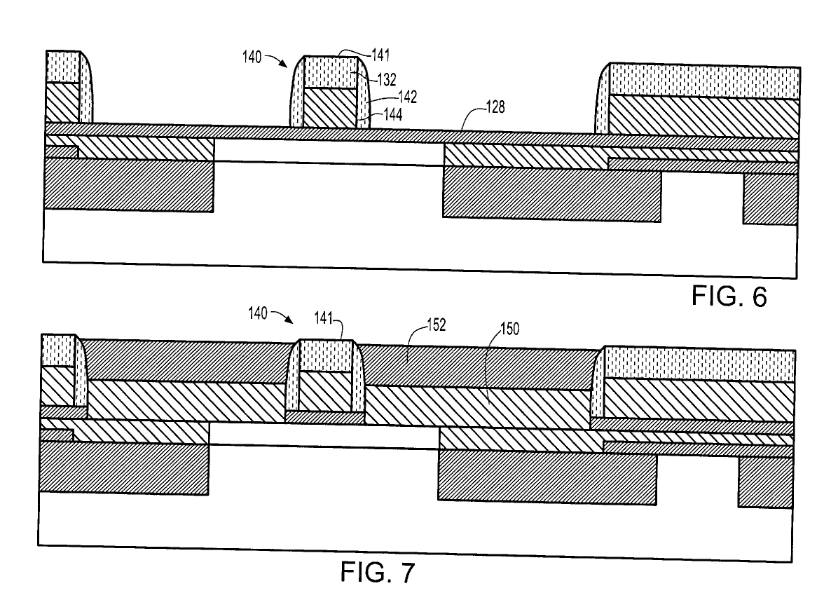

Thereafter, as shown in FIG. 5, an etch stop layer 128, also referred to as a “passivation oxide” is formed on the structure, e.g., by a thermal process or by an oxide deposition from a TEOS (tetraethylorthosilicate) precursor. Thereafter, a layer 130 of polycrystalline semiconductor material and an overlying layer 132 of silicon nitride are deposited to cover the structure. Layers 130 and 132 are then patterned by photolithography and vertical etching, e.g., by a reactive ion etch, stopping at the oxide etch stop layer 128, to form an emitter mandrel 140, having a mandrel nitride layer 132 and a mandrel polysilicon layer 130, as shown in FIG. 6. After photolithographic patterning, a first (e.g. replaceable or disposable) dielectric spacer 142 is formed on a sidewall 144 of the mandrel, as shown in FIG. 6, such as by depositing a layer of silicon nitride and vertically etching the structure, stopping on the oxide etch stop layer 128.

In a subsequent stage of processing shown in FIG. 7, the etch stop layer is removed from portions of the substrate which are not covered by the mandrel 140, after which a layer 150 of p+ doped polysilicon and an overlying layer 152 of dielectric material, e.g., an oxide of silicon, are formed in a region surrounding the mandrel 140. Eventually, the layer 150 of doped polysilicon will form the raised extrinsic base of the bipolar transistor. These layers are preferably formed by depositing polysilicon and thereafter planarizing the layer, for example, by chemical mechanical polishing (CMP) to the top surface 141 of the mandrel, after which the polysilicon is recessed, such as by a reactive ion etch process performed selectively to silicon nitride. Thereafter, the oxide layer 152 is deposited, planarized by CMP, and recessed to the level at or below the top surface 141 of the mandrel.

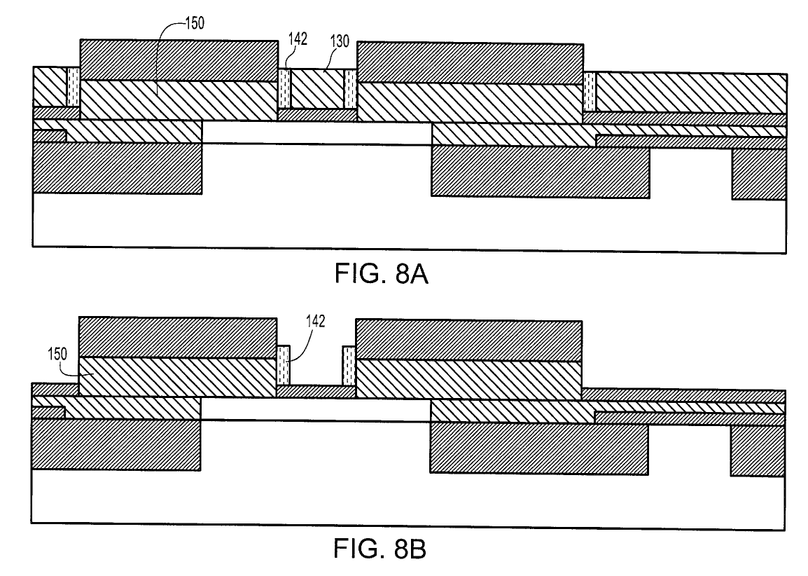

Next, RIE processing is used to remove the mandrel nitride layer, selectively to silicon oxide and to polysilicon to produce the structure shown in FIG. 8A. Then, RIE processing, followed by one or more cleaning processes, is further used to remove the polysilicon layer 130 of the mandrel. As shown in FIG. 8B, the first nitride spacer 142 is recessed and eroded as a consequence of the foregoing RIE processing. Damage to the spacer may further worsen its dielectric properties and structural integrity, causing the spacer to no longer provide adequate isolation between the emitter and the raised extrinsic base layer 150. In addition, erosion of the spacer may be greater for some transistors in some locations of a wafer, substrate or of an integrated circuit or “chip” than it is for other transistors. Erosion of the spacer, if not properly addressed, could cause the final critical dimensioned width of the emitter for some transistors at some locations of the wafer, substrate or chip to vary relative to other transistors at other locations of the wafer, substrate or chip, which is highly undesirable.

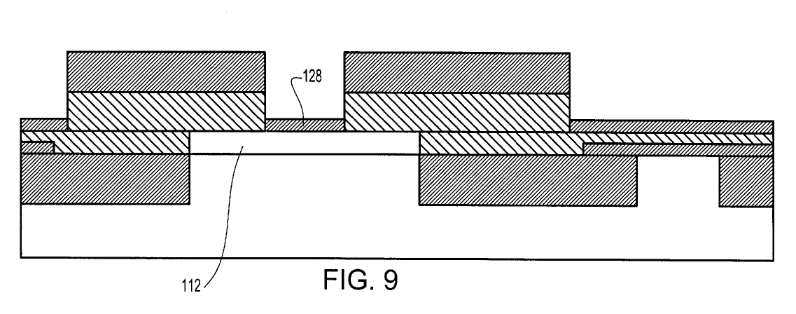

FIG. 9 shows a subsequent stage of processing, after the first nitride spacer has been removed by an additional etch process, for example. The remaining part of the first nitride spacer is preferably removed using a wet etch, such as using hot phosphoric acid having high selectivity to oxide and to polysilicon. After such etch, the oxide layer 128 continues to cover and protect the intrinsic base layer 112 that lies below the location of the emitter yet to be formed.

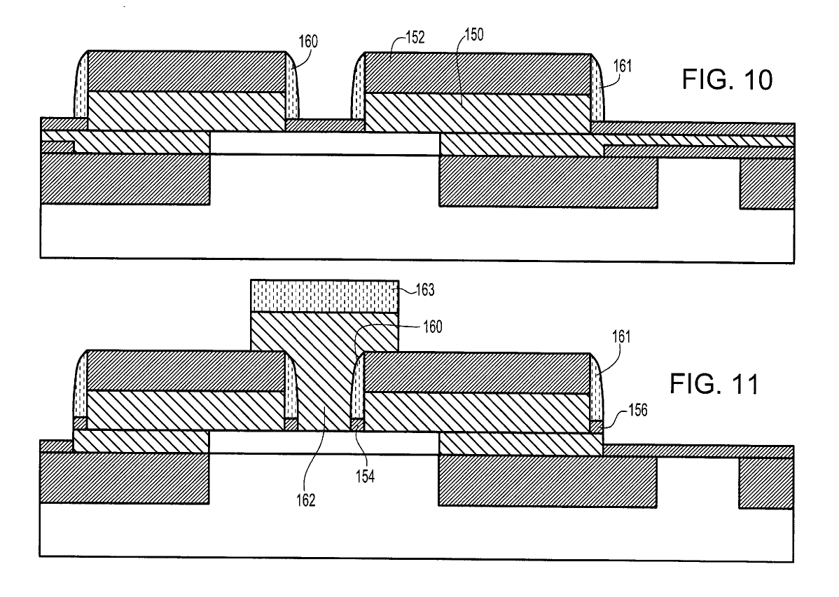

Next, as shown in FIG. 10, a final (or second) isolating spacer 160 is formed on a sidewall of the raised extrinsic base layer 150 and top oxide layer 152. The final spacer 160 preferably consists essentially of silicon nitride. This spacer 160 is a newly formed or “pristine” spacer not subjected to extended RIE processing the way that the original spacer 142 (FIGS. 8A-B) was. As a result, its height and thickness can be controlled better in relation to the isolation to be achieved between the raised extrinsic base layer 150 and the subsequently formed emitter 162 (FIG. 11). Spacer 160 also results in a much more uniform and controlled final critically dimensioned width of the emitter 162. Through this processing, an outer spacer 161 of silicon nitride is also formed on an outer sidewall of the raised extrinsic base layer 150.

Thereafter, FIG. 11 shows a stage of processing after the dielectric etch stop layer or “passivation oxide” has been removed through a wet etch having selectivity to polysilicon and to nitride, to leave annular rings 154, 156 of the passivation oxide underlying the final nitride spacer 160 and the outer spacer 161, respectively. A layer of polysilicon is then deposited to fill the opening defined by the final nitride spacer 160 as an emitter 162. A hard mask layer consisting essentially of, e.g., silicon nitride, is then deposited to overlie the deposited polysilicon layer, after which the hard mask and polysilicon layers are patterned by RIE processing in accordance with a photolithographically defined resist pattern (not shown). As a result, an emitter cap layer 163 consisting essentially of, e.g., silicon nitride is formed to overlie the emitter.

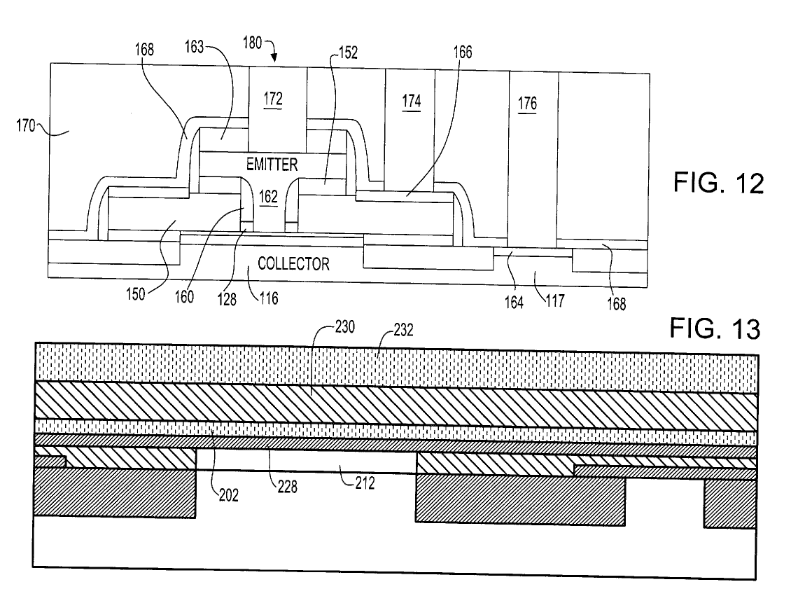

Referring to FIG. 12, a completed bipolar transistor 180 is shown. The transistor 180 is completed by subsequent processing including the removal of a portion of the top oxide layer 152 from the region overlying the raised extrinsic base layer 150, such processing also removing the outer spacer and the oxide layer from overlying a collector reach-through region disposed in active area 117. Thereafter, silicide layers 164, 166 are formed on the raised extrinsic base layer 150 and the collector reach-through region, followed by deposition of a thin silicon nitride layer 168 as an etch stop layer overlying the structure and overlying the emitter cap layer 163. An interlevel dielectric region 170 is then formed over the structure, and contact vias 172, 174, and 176 are etched and filled with a metal, conductive compound of a metal, semiconductor and/or conductive compound of a semiconductor such as, e.g., a metal silicide, for form conductive contact vias to the emitter 162, the raised extrinsic base layer 150, and the collector 116 via the reach-through region, respectively. In the completed transistor, the emitter 162 is isolated from the raised extrinsic base 150 by the nitride spacer 160 and the portion of the oxide layer 128 which remains beneath it as an oxide spacer.

Another embodiment of the invention will now be described, with reference to FIGS. 13 through 19. In this embodiment, an additional etch stop layer is provided during processing for the purpose of protecting the oxide layer 128 (FIG. 12) that remains under the final nitride spacer 160 of the transistor 180. FIG. 13 shows a stage of processing similar to that shown and described above with respect to FIG. 5. FIG. 13 shows a stage of processing after an intrinsic base layer 212 is formed on the substrate, and a passivation oxide layer 228 is provided, after which a RIE etch stop layer 202 is formed, preferably consisting of silicon nitride or other material which is etch distinguishable from silicon oxide or which can be etched in preference to silicon oxide. Thereafter, the mandrel polysilicon layer 230 and mandrel nitride layer 232 are formed.

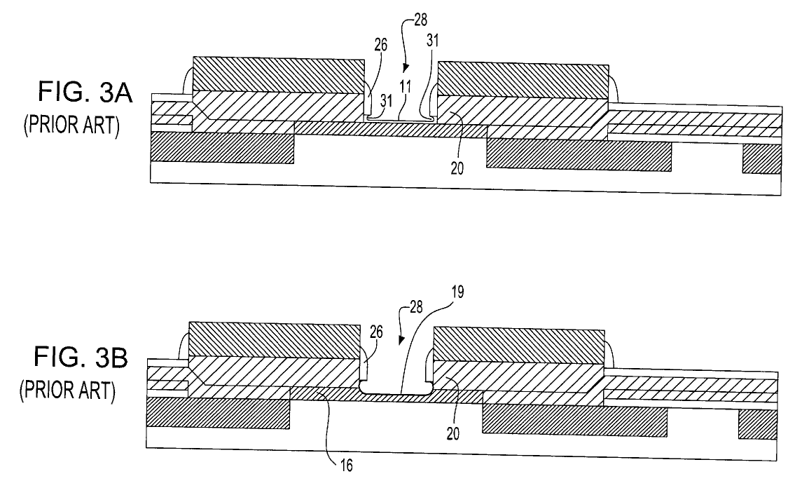

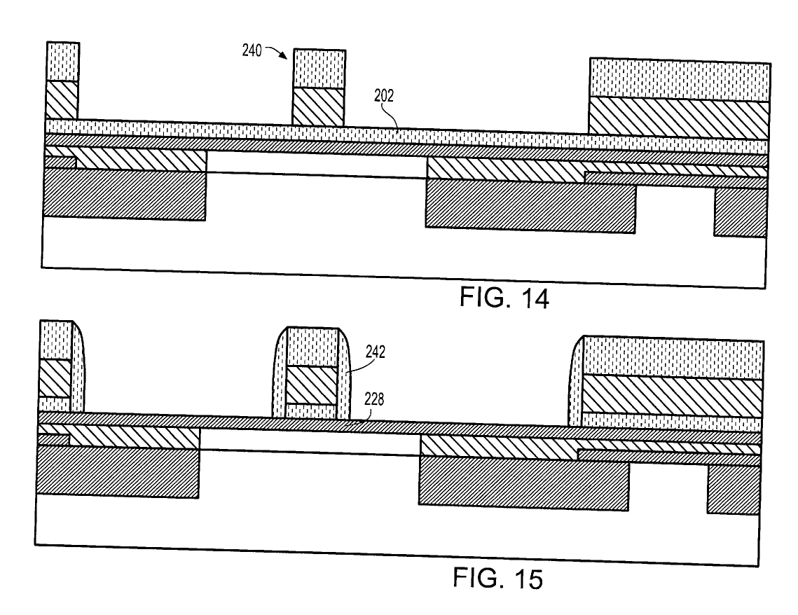

In the subsequent stage of processing shown in FIG. 14, the mandrel nitride layer and mandrel polysilicon layer are patterned by RIE to form a mandrel 240, the RIE process stopping on the nitride etch stop layer 202. The etch stop layer 202 protects the passivation oxide from damage during RIE processing and subsequent cleaning processes. Thus, the etch stop layer 202 protects against potential damage to the passivation oxide of the kind shown in FIGS. 3A and 3B above. Moreover, the etch stop layer 202 helps avoid undercutting of the passivation oxide layer which could otherwise worsen control over the width and thickness of the passivation oxide that separates the emitter from the raised extrinsic base in the transistor when completed.

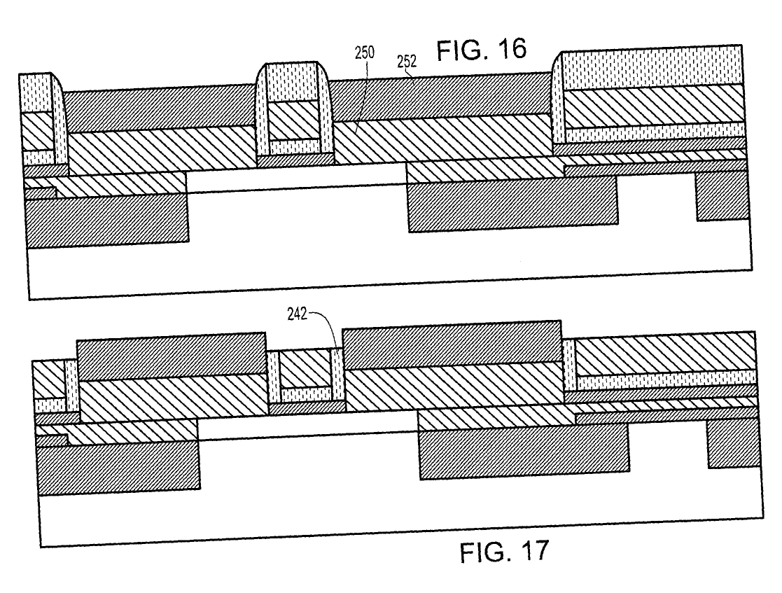

As shown in FIG. 15, a layer of silicon nitride is deposited and etched by RIE in a manner selective to oxide to form a first or disposable spacer 242. The etching of the first spacer 242 removes the nitride etch stop layer where the raised extrinsic base is to be formed at a later time. The layer 228 of passivation oxide underlying the spacer 242 remains protected by the spacer during this etch. Thereafter, as shown in FIG. 16, the exposed “passivation oxide” is removed through a wet etch, after which a layer of polysilicon is deposited and recessed to form a raised extrinsic base layer 250. Thereafter, an oxide is deposited and recessed to form oxide layer 252.

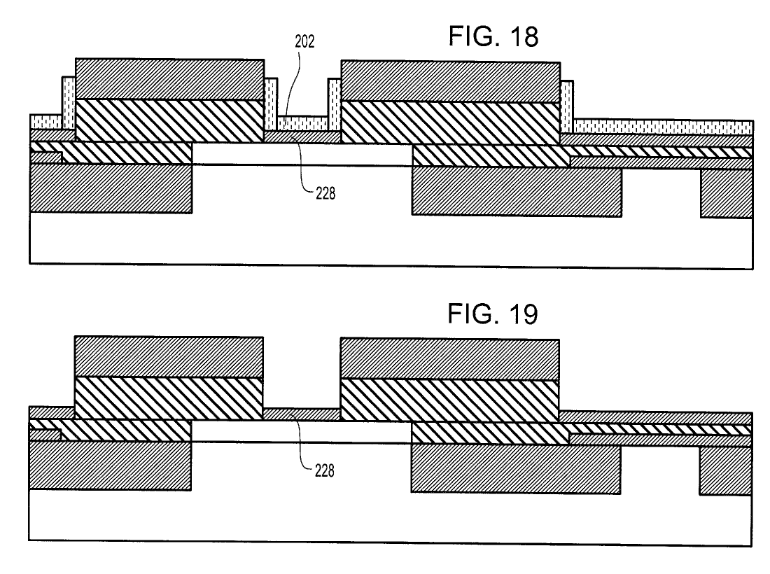

Thereafter, the mandrel nitride layer is then removed, resulting in the structure shown in FIG. 17 in which the nitride spacer 242 has become eroded. The mandrel polysilicon layer is then removed by RIE processing (FIG. 18) in a manner which is selective to silicon nitride. Throughout this RIE processing, the passivation oxide layer 228 remains protected by the overlying nitride etch stop layer 202.

Thus, when the nitride etch stop layer and the first spacer are subsequently removed (FIG. 19) the underlying passivation oxide layer 228 is essentially undamaged, not having undergone etching including over-etch and cleaning processes for removing the overlying mandrel polysilicon layer. Thereafter, further processing is conducted to complete the bipolar transistor in a manner such as described above with reference to FIGS. 10 through 12.

Many variations and alternative embodiments of the invention can be made without departing from the scope of the invention. For example, in a particular embodiment, a passivation layer consisting essentially of silicon nitride is used in place of a passivation oxide layer 228 (FIG. 15). In addition, a spacer consisting essentially of an oxide can be used in place of a silicon nitride spacer 242, as described above with reference to FIG. 15. In such embodiment, an etch stop layer which preferably consists essentially of an oxide of silicon is used instead of the nitride etch stop layer. Finally, a layer of silicon dioxide, rather than a layer of silicon nitride, can also be used to cover the polysilicon layer of the mandrel 240 (FIG. 14). In such method, the selectivities of the etch processes will be altered such that the nitride passivation layer is selectively preserved when the oxide which overlies that layer is removed by etching. In such manner, function of the oxide spacer and passivation nitride will be the same at that of the nitride spacer and passivation oxide described above but the position of the vertically extending oxide spacer relative to the passivation nitride will be reversed.

While the invention has been described in accordance with certain preferred embodiments thereof, those skilled in the art will understand the many modifications and enhancements which can be made thereto without departing from the true scope and spirit of the invention, which is limited only by the claims appended below.

What is claimed is:

1. A method of making a bipolar transistor, comprising:
forming a portion of said bipolar transistor including a collector region, an intrinsic base layer overlying said collector region, a mandrel having an upwardly rising wall overlying a first portion of said intrinsic base layer, a replaceable dielectric spacer disposed on said wall of said mandrel, and a raised extrinsic base layer overlying a second portion of said intrinsic base layer;
etching to remove said mandrel to form an emitter opening having an upwardly rising wall; and
forming a replacement dielectric spacer on said wall of said emitter opening and forming an emitter layer separated from said raised extrinsic base layer by at least said replacement dielectric spacer.

2. The method as claimed in claim 1, wherein said step of etching to remove said mandrel at least partially removes said first dielectric spacer.

3. The method as claimed in claim 2, wherein said step of forming said portion of said bipolar transistor includes forming an etch stop layer between said intrinsic base layer and said mandrel, and said step of etching to remove said mandrel includes reactive ion etching said mandrel selective to a material of said etch stop layer.

4. The method as claimed in claim 3, wherein said reactive ion etching is performed selective to a material of said replaceable spacer.

5. The method as claimed in claim 3, wherein said etch stop layer includes a layer of oxide deposited to overlie said intrinsic base layer and a layer of nitride deposited to overlie said layer of oxide.

6. The method as claimed in claim 5, wherein said mandrel is formed by depositing and patterning a layer of polysilicon to overlie said etch stop layer and said step of etching to remove said mandrel further includes etching said polysilicon layer selective to said layer of nitride, etching to remove said layer of nitride, and etching to remove said layer of oxide.

7. The method as claimed in claim 1, wherein said replacement dielectric spacer has a first upwardly rising wall and a second upwardly rising wall opposite said first wall, said first wall contacting said raised extrinsic base layer and said second wall contacting said emitter layer.

8. The method as claimed in claim 5, wherein said replacement dielectric spacer consists essentially of silicon nitride.

9. The method as claimed in claim 1, wherein said step of forming said portion of said bipolar transistor includes depositing a first layer including silicon nitride to overlie said intrinsic base layer and depositing a second layer including silicon oxide to overlie said first layer, said mandrel being formed to overlie said second layer, and said step of etching to remove said mandrel includes reactive ion etching said mandrel selective to a material of said second layer.

10. A method of making a bipolar transistor, comprising:
forming a portion of said bipolar transistor including a collector region, an intrinsic base layer overlying said collector region, a mandrel having an upwardly rising wall overlying a first portion of said intrinsic base layer, and a raised extrinsic base layer overlying a second portion of said intrinsic base layer, said mandrel being separated from said intrinsic base layer by a first layer consisting essentially of a first dielectric material and a second layer consisting essentially of a second dielectric material overlying said first dielectric material;
etching to remove said mandrel to form an emitter opening having an upwardly rising wall;
etching said second layer selective to said first dielectric material;
etching said first layer; and
forming an emitter layer in conductive communication with said intrinsic base layer from within said emitter opening.

11. The method as claimed in claim 10, wherein said step of forming said portion of said bipolar transistor includes forming a dielectric spacer on a wall of said mandrel prior to forming said raised extrinsic base and said step of etching to remove said mandrel includes reactive ion etching said mandrel selective to a material of said dielectric spacer.

12. The method as claimed in claim 11, wherein said first layer consists essentially of a layer of oxide and said second layer consists essentially of a layer of nitride.

13. The method as claimed in claim 12, wherein said mandrel is formed by depositing and patterning a layer of polysilicon to overlie said second layer and said step of etching to remove said mandrel further includes etching said polysilicon layer selective to said second layer, etching to remove said second layer selective to oxide, and etching to remove said first layer.

14. The method as claimed in claim 11, wherein said first layer consists essentially of a layer of nitride and said second layer consists essentially of a layer of oxide.

15. The method as claimed in claim 14, wherein said mandrel is formed by depositing and patterning a layer of polysilicon to overlie said second layer and said step of etching to remove said mandrel further includes etching said polysilicon layer selective to said second layer, etching to remove said second layer selective to nitride, and etching to remove said first layer.

16. A bipolar transistor, comprising:
a collector region;
an intrinsic base layer overlying said collector region;
a raised extrinsic base layer in conductive communication with said intrinsic base layer;
an emitter layer in conductive communication with said intrinsic base layer; and
a spacer separating said raised extrinsic base layer from said emitter layer, said spacer having a lower layer consisting essentially of a first dielectric material, and an upper layer disposed above said lower layer consisting essentially of a second dielectric material, said spacer having a uniform, controllable thickness.

17. The bipolar transistor as claimed in claim 16, wherein said spacer is free of ion etch damage.

18. The bipolar transistor as claimed in 17, wherein said lower layer includes a deposited passivation oxide contacting an upper surface of said intrinsic base layer, and said passivation oxide has a good dielectric property isolating an edge of said raised extrinsic base layer from an edge of said emitter layer.
